(19) United States
(12) Patent Application Publication
(10) Pub. No.: US 2002/0111013 A1
(43) Pub. Date: Aug. 15, 2002

(54) Method for formation of single inlaid structures

(76) Inventors: Lynn A. Okada, Sunnyvale, CA (US); Fei Wang, San Jose, CA (US)

Correspondence Address: MCDERMOTT WILL & EMERY, 600 13TH STREET, N.W., WASHINGTON, DC, 20005-3096, US

(21) Appl. No.: 09/783,284

(22) Filed: Feb. 15, 2001

(51) Int. Cl. H01L 21/4763

(52) U.S. Cl. 438/627; 438/624; 438/636

(57) ABSTRACT

A method is provided for manufacturing Cu interconnects without sputtering freed Cu onto dielectric material and without additional costly process steps. Embodiments include forming a nitride layer cap layer on an underlying conductive feature, such as a Cu feature, forming a dielectric insulating layer, such as a silicon dioxide layer, on the nitride cap layer, and etching in a conventional manner to form a through hole exposing the cap layer above the Cu feature. A metal barrier layer is formed on the sidewalls of the through hole, as by physical vapor deposition (PVD), and the nitride cap layer is etched along with the barrier layer, as by anisotropic etching, to expose the Cu feature. A metal, such as Cu, is then plated, as by electroplating or electroless plating, on the exposed Cu feature and on the barrier layer and filling the through hole. Due to the presence of the barrier layer, freed Cu from the exposed upper surface of the Cu feature redeposits on the barrier layer during the nitride cap etching step, rather than on the dielectric layer. Thus, Cu diffusion through the dielectric layer is avoided. Moreover, since the metal filling the through hole is plated directly on the barrier layer, no additional processing steps are required.

### FIELD OF THE INVENTION

The present invention relates to semiconductor devices having accurately dimensioned interconnection patterns. The present invention is particularly applicable to ultra large-scale integrated circuit (ULSI) devices having features in the deep sub-micron regime.

### BACKGROUND ART

As integrated circuit geometries continue to plunge into the deep sub-micron regime, it has become increasingly difficult to satisfy the requirements for dimensional accuracy, particularly in integration technology, which is considered one of the most demanding aspects of fabricating ULSI devices. Demands for ULSI semiconductor wiring require increasingly denser arrays with minimal spacings between narrow conductive lines. Implementation becomes problematic in manufacturing semiconductor devices having a design rule of about 0.12 micron and under.

Conventional semiconductor devices comprise a semiconductor substrate, typically doped monocrystalline silicon, and a plurality of sequentially formed interlayer dielectrics and conductive patterns. An integrated circuit is formed containing a plurality of conductive patterns comprising conductive lines separated by interwiring spacings, and a plurality of interconnect lines, such as bus lines, bit lines, word lines and logic interconnect lines. Typically, the conductive patterns on different levels, i.e., upper and lower levels, are electrically connected by a conductive plug filling a via hole, while a conductive plug filling a contact hole establishes electrical contact with an active region on a semiconductor substrate, such as a source/drain region. Conductive lines are formed in trenches which typically extend substantially horizontal with respect to the semiconductor substrate. Semiconductor “chips” comprising five or more levels of metallization are becoming more prevalent as feature sizes shrink into the deep sub-micron regime.

A conductive plug filling a via hole is typically formed by depositing an interlayer dielectric (ILD) on a patterned conductive layer comprising at least one conductive feature, forming an opening through the ILD by conventional photolithographic and etching techniques, and filling the opening with a conductive material. The excess conductive material or overburden on the surface of the ILD is typically removed by chemical-mechanical polishing (CMP). One such method is known as damascene and basically involves forming an opening in the ILD and filling the opening with a metal. Dual damascene techniques involve forming an opening comprising a lower contact or via hole section in communication with an upper trench section, which opening is filled with a conductive material, typically a metal, to simultaneously form a conductive plug in electrical contact with a conductive line.

Copper (Cu) and Cu alloys have received considerable attention as alternative metallurgy to aluminum (Al) in interconnect metallizations. Cu is relatively inexpensive, easy to process, and has a lower resistivity than Al. In addition, Cu has improved electrical properties vis-a-vis tungsten (W), making Cu a desirable metal for use as a conductive plug as well as conductive wiring. However, due to Cu diffusion through dielectric materials, such as silicon dioxide, which adversely affects device performance, Cu interconnect structures must be encapsulated by a diffusion barrier layer. Typical diffusion barrier materials include tantalum (Ta), tantalum nitride (TaN), titanium nitride (TiN), titanium-tungsten (TiW), tungsten (W), tungsten nitride (WN), Ti—TiN, titanium silicon nitride (TiSiN), tungsten silicon nitride (WSiN), tantalum silicon nitride (TaSiN) and silicon nitride for encapsulating Cu. The use of such barrier materials to encapsulate Cu is not limited to the interface between Cu and the ILD, but includes interfaces with other metals as well.

Cu interconnect technology has, by and large, been implemented employing damascene techniques, wherein a first dielectric layer, such as a silicon oxide layer, e.g., derived from tetraethyl orthosilicate (TEOS) or silane, or a low dielectric constant material, i.e., a material having a dielectric constant of no greater than 4 (with a dielectric constant of 1 representing a vacuum), is formed over an underlying pattern of conductive features having a capping layer thereon, e.g., a Cu or Cu alloy pattern with a silicon nitride capping layer. A patterned photoresist layer is formed on the dielectric layer, and the dielectric layer is etched to form a through hole exposing the cap layer directly above the conductive feature. The photoresist is then stripped off, and the nitride cap layer at the bottom of the through hole is etched away. A barrier layer and optional seed layer are then deposited, followed by Cu deposition, as by electrodeposition or electroless deposition, to fill the through hole.

It has been found that during the nitride cap etching step, some Cu is freed from the exposed upper surface of the Cu feature. As a result, the freed Cu redeposits or “sputters” onto the sidewalls of the through hole in the dielectric layer, thereby undermining the objective of forming the barrier layer, since the redeposited freed Cu readily diffuses through the dielectric layer into silicon elements, adversely affecting device performance.

One approach to solving this problem is found in U.S. Pat. No. 6,066,557, which discloses forming a first barrier layer on the sidewalls of the through hole prior to etching the nitride cap layer. Thus, during the nitride cap etching step, freed Cu from the exposed upper surface of the Cu feature redeposits on the barrier layer, rather than on the dielectric layer. The first barrier layer is thereafter removed along with the freed redeposited Cu, and a second, final barrier layer is formed before plating and filling the through hole with Cu. Disadvantageously, the methodology of U.S. Pat. No. 6,066,557 requires an added barrier layer removal step and a second barrier layer formation step, which extra steps increase manufacturing costs, reduce production throughput and potentially reduce yield.

There exists a need for a methodology for manufacturing encapsulated Cu interconnect members which eliminates Cu diffusion and does not increase manufacturing costs or lower production throughput and yield.

### SUMMARY OF THE INVENTION

An advantage of the present invention is a method of manufacturing Cu interconnects without sputtering freed Cu onto dielectric material and without additional costly process steps.

Additional advantages and other features of the present invention will be set forth in part in the description which follows and in part will become apparent to those having ordinary skill in the art upon examination of the following or may be learned from the practice of the invention. The advantages of the invention may be realized and obtained as particularly pointed out in the appended claims.

According to the present invention, the foregoing and other advantages are achieved in part by a method of manufacturing a semiconductor device, the method comprising forming a nitride layer on an underlying conductive feature comprising a first metal; forming an insulating layer on the nitride layer; forming a through hole in the insulating layer, the through hole having side surfaces and exposing a portion of the upper surface of the nitride layer; depositing a barrier layer on the insulating layer, on the side surfaces of the through hole and on the exposed portion of the nitride layer; removing a portion of the barrier layer from the nitride layer; removing the exposed portion of the nitride layer to expose a portion of the underlying conductive feature, wherein the barrier layer substantially prevents the first metal from the underlying conductive feature from depositing on the side surfaces of the through hole; and plating a second metal on the exposed portion of the underlying conductive feature and on the barrier layer and filling the through hole.

Additional advantages of the present invention will become readily apparent to those skilled in this art from the following detailed description, wherein only the preferred embodiment of the present invention is shown and described, simply by way of illustration of the best mode contemplated for carrying out the present invention. As will be realized, the present invention is capable of other and different embodiments, and its several details are capable of modifications in various obvious respects, all without departing from the invention. Accordingly, the drawings and description are to be regarded as illustrative in nature, and not as restrictive.

### BRIEF DESCRIPTION OF THE DRAWINGS

Reference is made to the attached drawings, wherein elements having the same reference numeral designations represent like elements throughout, and wherein:

FIGS. 1A-1F schematically illustrate sequential phases of a method in accordance with an embodiment of the present invention.

### DESCRIPTION OF THE INVENTION

Conventional methodologies for manufacturing encapsulated Cu interconnect members result in unwanted Cu diffusion or increase the cost of the finished device and reduce manufacturing yield. The present invention addresses and solves these problems stemming from conventional manufacturing processes.

According to the methodology of the present invention, a nitride layer cap layer is formed on an underlying conductive feature, such as a Cu feature, then a dielectric insulating layer, such as a silicon dioxide layer, is formed on the nitride cap layer and etched in a conventional manner to form a through hole exposing the cap layer above the Cu feature. A metal barrier layer is formed on the sidewalls of the through hole, as by physical vapor deposition (PVD), and the nitride cap layer is etched along with the barrier layer, as by anisotropic etching, to expose the Cu feature. A metal, such as Cu, is thereafter plated, as by electroplating or electroless plating, on the exposed Cu feature and on the barrier layer and filling the through hole. Due to the presence of the barrier layer, freed Cu from the exposed upper surface of the Cu feature redeposits on the barrier layer during the nitride cap etching step, rather than on the dielectric layer. Thus, Cu diffusion through the dielectric layer is avoided. Moreover, since the metal filling the through hole is plated directly on the barrier layer, no additional processing steps are required.

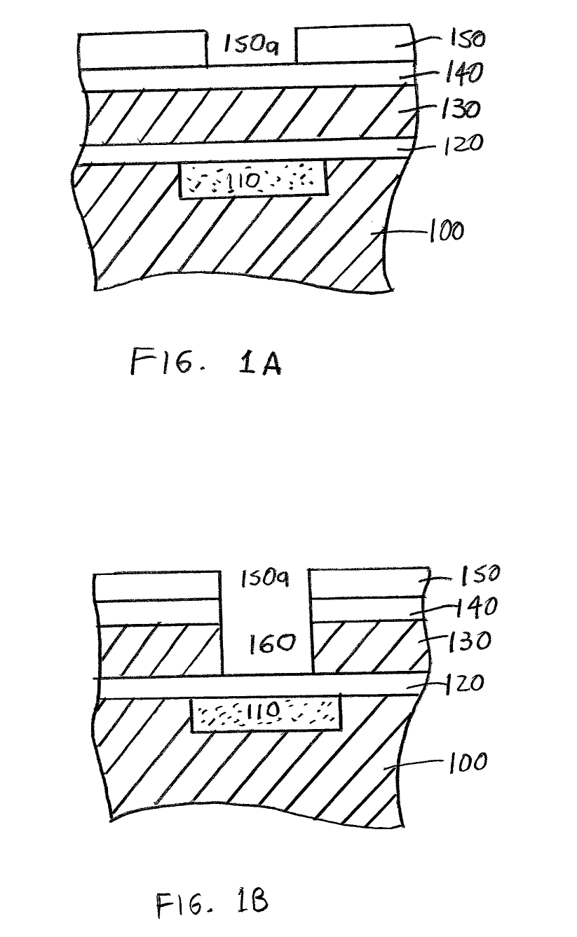

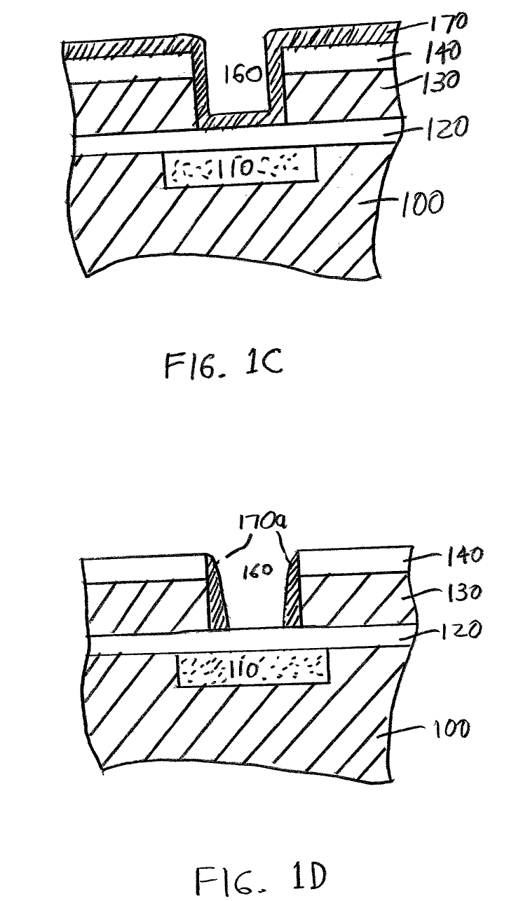

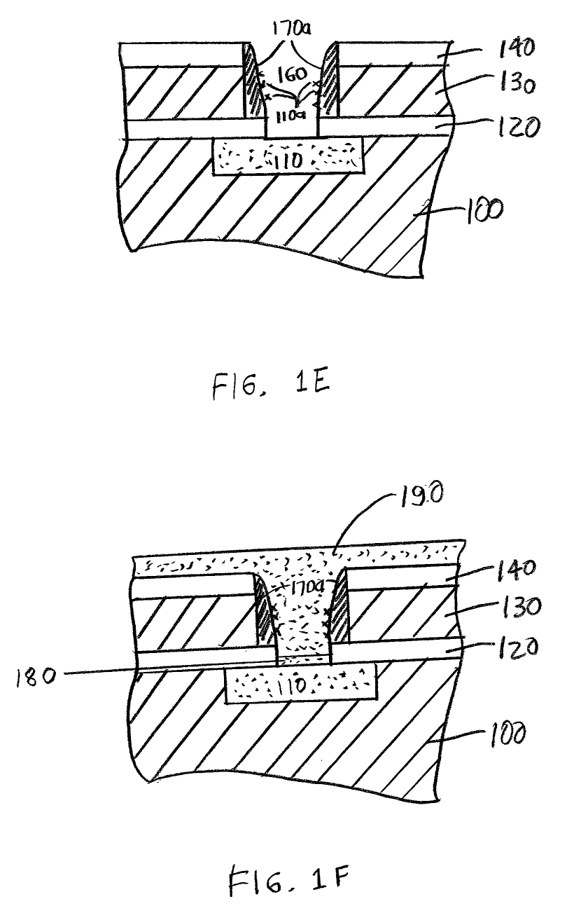

An embodiment of the present invention will now be described with reference to FIGS. 1A-1F. As shown in FIG. 1A, a conductive feature 110, such as a Cu or Cu alloy metallization structure, is formed in a dielectric layer 100 in a conventional manner, and a nitride layer 120 is formed on the surface of conductive feature 110, such as a silicon nitride or silicon oxynitride layer. An insulating layer 130, typically an oxide, is then deposited on the nitride layer 120, and an anti-reflective coating (ARC) layer 140, such as silicon nitride or silicon oxynitride, is deposited on insulating layer 130. A photoresist mask 150 having an opening 150a corresponding to conductive feature 110 is thereafter formed on ARC layer 140.

With reference to FIG. 1B, a through hole 160 is formed exposing the upper surface of nitride layer 120, as by etching through ARC layer 140 and insulating layer 130. Conductive feature 110 has a width greater than that of through hole 160 (i.e., greater than mask opening 150a), and through hole 160 is formed aligned with conductive feature 110 such that the width of through hole 160 is disposed entirely within the width of conductive feature 110. In this way, the subsequently formed metal via filling through hole 160 is “landed” or “bordered”; that is, approximately centered above conductive feature 110 so that the via metal does not contact dielectric layer 100. Photoresist mask 150 is then stripped in a conventional manner, as with an O₂-containing plasma. A barrier metal layer 170 is then deposited in a conventional manner on ARC layer 140, on the side surface of through hole 160 and on the exposed portion of nitride layer 120, as shown in FIG. 1C. Barrier layer 170 must be impervious to Cu diffusion and typically comprises, for example, a tantalum layer or a “bi-layer” of tantalum and tantalum nitride deposited by PVD, wherein the tantalum nitride is deposited first and so is in contact with insulating layer 130.

Next, as shown in FIG. 1D, barrier layer 170 is anisotropically etched to remove it from nitride layer 120 and ARC layer 140, thereby forming a spacer 170a on the sidewalls of through hole 160. Etching is then conducted to remove underlying nitride layer 120 and extend through hole 160, exposing a portion of underlying conductive feature 110 (see FIG. 1E). Thereafter, the exposed portion of underlying conductive feature 110 is cleaned, as with hydrogen, nitrogen or ammonia, to remove unwanted copper oxide. The presence of spacer 170a prevents free Cu, such as Cu 110a freed during the etching of nitride layer 120 and during the cleaning step, from depositing on the sidewalls of through hole 160, because the freed copper 110a instead deposits on spacer 170a.

Referring now to FIG. 1F, a seed layer 180 of Cu or Cu alloy is formed, as by PVD, on the exposed portion of conductive feature 110 in a conventional manner, then a Cu or Cu alloy layer 190 is electroplated or electroless plated on seed layer 180, on the surface of spacer 170a and and filling through hole 160. Subsequent conventional processing steps, though not illustrated, typically include planarizing the upper surface of Cu or Cu alloy layer 190 by chemical mechanical polishing, and cleaning the planarized upper surface.

In an alternative embodiment of the present invention, the width of through hole 160 is enlarged slightly compared to normal design rules for vias, to compensate for the narrowing of the via at the bottom that occurs due to the presence of a portion of nitride layer 120 under spacer 170a.

The present invention is applicable to the manufacture of various types of semiconductor devices, particularly high-density semiconductor devices having a design rule of about 0.18 μ and under.

The present invention can be practiced by employing conventional materials, methodology and equipment. Accordingly, the details of such materials, equipment and methodology are not set forth herein in detail. In the previous descriptions, numerous specific details are set forth, such as specific materials, structures, chemicals, processes, etc., in order to provide a thorough understanding of the present invention. However, it should be recognized that the present invention can be practiced without resorting to the details specifically set forth. In other instances, well known processing structures have not been described in detail, in order not to unnecessarily obscure the present invention.

Only the preferred embodiment of the present invention and but a few examples of its versatility are shown and described in the present disclosure. It is to be understood that the present invention is capable of use in various other combinations and environments and is capable of changes or modifications within the scope of the inventive concept as expressed herein.

What is claimed is:

1. A method of manufacturing a semiconductor device, the method comprising:
forming a nitride layer on an underlying conductive feature comprising a first metal;
forming an insulating layer on the nitride layer;
forming a through hole in the insulating layer, the through hole having side surfaces and exposing a portion of the upper surface of the nitride layer;
depositing a barrier layer on the insulating layer, on the side surfaces of the through hole and on the exposed portion of the nitride layer;
removing a portion of the barrier layer from the nitride layer;
removing the exposed portion of the nitride layer to expose a portion of the underlying conductive feature, wherein the barrier layer substantially prevents the first metal from the underlying conductive feature from depositing on the side surfaces of the through hole; and
plating a second metal on the exposed portion of the underlying conductive feature and on the barrier layer and filling the through hole.

2. The method of claim 1, wherein the nitride layer comprises silicon nitride or silicon oxynitride.

3. The method of claim 1, wherein the insulating layer comprises an oxide.

4. The method of claim 1, comprising anisotropically etching to remove the portion of the barrier layer from the nitride layer.

5. The method of claim 1, wherein the barrier layer comprises a layer of tantalum nitride and a layer of tantalum.

6. The method of claim 1, wherein the barrier layer comprises tantalum.

7. The method of claim 1, wherein the first and second metals comprise copper or a copper alloy.

8. The method of claim 7, comprising treating the exposed portion of the underlying conductive feature with hydrogen, nitrogen or ammonia prior to the plating step.

9. The method of claim 1, comprising:
forming an anti-reflective coating (ARC) layer on the insulating layer prior to forming the through hole;
etching a portion of the ARC layer prior to forming the through hole;
forming the barrier layer on the ARC layer; and
removing a portion of the barrier layer from the ARC layer when the portion of the barrier layer on the nitride layer is removed.

10. The method of claim 9, comprising:
forming the through hole by forming a patterned photoresist mask on the ARC layer;
etching the portion of the ARC layer and the insulating layer to form the through hole; and
removing the photoresist from the insulating layer.

11. The method of claim 1, comprising electroless plating or electroplating the second metal.

12. The method of claim 1, wherein the underlying conductive feature has a width greater than a width of the through hole, the method comprising forming the through hole aligned with the conductive feature such that the width of the through hole is disposed entirely within the width of the conductive feature.

13. The method of claim 9, wherein the ARC layer comprises silicon nitride or silicon oxynitride.
